(19) United States
(12) Patent Application Publication
(10) Pub. No.: US 2024/0249989 A1
(43) Pub. Date: Jul. 25, 2024

(54) Selectively Dispensed Underfill and Edge Bond Patterns

(71) Applicant: Apple Inc., Cupertino, CA (US)

(72) Inventors: Wei Chen, San Jose, CA (US); Balaji Nandhivaram Muthuraman, Reutlingen (DE); Arun Sasi, Kirchheim unter Teck (DE); Jie-Hua Zhao, Cupertino, CA (US); Suk-Kyu Ryu, Cupertino, CA (US); Jun Zhai, Cupertino, CA (US); Dominic Morache, Santa Clara, CA (US); Young Doo Jeon, San Jose, CA (US)

(21) Appl. No.: 18/158,090

(22) Filed: Jan. 23, 2023

(51) Int. Cl. H01L 23/31; H01L 23/00; H01L 23/34

(52) U.S. Cl. CPC H01L 23/3157; H01L 23/34; H01L 24/16; H01L 24/17; H01L 2224/16113; H01L 2224/16225; H01L 2224/17055; H01L 2924/10162; H01L 2924/1811; H01L 2924/182

(57) ABSTRACT

Microelectronic structures with selectively applied underfill material and/or edge bond material are described. In an embodiment, isolated underfill regions and/or edge bond regions are applied to adjacent to one or more edges of an electronic device and form a plurality of vent openings along the one or more edges.

### BACKGROUND

### Field

Embodiments described herein relate to microelectronic packaging.

### Background Information

Microelectronic packages may commonly be bonded to a substrate such as a printed circuit board (PCB) or interposer with an array of solder balls/bumps which can provide electrical and mechanical connection. Underfill or edge bonding materials such as filled epoxy may commonly be applied to further secure the package to the substrate and improve reliability of the solder balls/bumps.

### SUMMARY

In an embodiment, a microelectronic structure includes a substrate, and an electronic device bonded to the substrate with an array of solder bumps. An underfill material is located between the electronic device and the substrate, where the underfill material includes a plurality of isolated underfill regions adjacent to one or more edges of the electronic device. Each isolated underfill material can encapsulate a corresponding group of solder bumps. A plurality of vent openings is additionally located along the one or more edges and between the plurality of isolated underfill regions. For example, the vent openings may be defined by the plurality of isolated underfill regions.

In an embodiment, a microelectronic structure includes a substrate, an electronic device bonded to the substrate with an array of solder bumps, and a plurality of isolated edge bond regions of an edge bond material adjacent to one or more edges of the electronic device. A plurality of vent openings is additionally located along the one or more edges and between the plurality of isolated edge bond regions. For example, the vent openings may be defined by the plurality of isolated edge bond regions.

In accordance with embodiments, hybrid structures are also described in which a combination of one or more isolated underfill regions and one or more isolated edge bond regions are applied to the same electronic device. Similarly, the vent openings may be defined by the combination of isolated underfill regions and/or isolated edge bond regions. Such underfill and edge bond techniques can be applied to a variety of electronic devices such as dies, packages, active/passive components, as well as routing substrates, and combinations thereof.

### BRIEF DESCRIPTION OF THE DRAWINGS

FIG. 1A is a schematic top-down view illustration of an underfill material with voids applied underneath an electronic component.

FIG. 1B is a schematic cross-sectional side view illustration taken along line B-B of FIG. 1A of an underfill material with voids applied underneath an electronic component.

FIG. 2A is a schematic top-down view illustration of a plurality of isolated underfill regions adjacent to one or more edges of an electronic device in accordance with an embodiment.

FIG. 2B is a schematic cross-sectional side view illustration taken along line B-B of FIG. 2A of a plurality of isolated underfill regions adjacent to one or more edges of an electronic device in accordance with an embodiment.

FIG. 3A is a schematic top-down view illustration of a plurality of isolated edge bond regions adjacent to one or more edges of an electronic device in accordance with an embodiment.

FIG. 3B is a schematic cross-sectional side view illustration taken along line B-B of FIG. 3A plurality of isolated edge bond regions adjacent to one or more edges of an electronic device in accordance with an embodiment.

FIGS. 4-5 are schematic top-down view illustrations of a plurality of isolated underfill regions and isolated edge bond regions adjacent to one or more edges of an electronic device in accordance with embodiments.

FIGS. 6-7 are schematic cross sectional side view illustrations of various microelectronic structures in accordance with embodiments.

### DETAILED DESCRIPTION

Embodiments describe microelectronic structures and methods of fabrication in which a plurality of isolated underfill regions and/or isolated edge bond regions are selectively applied adjacent to one or more edges of an electronic device.

In one aspect it has been observed that traditional underfill flow can be nonuniform when being applied underneath a large die or package. Specifically, voids may be trapped underneath the electronic component being bonded, which can subsequently result in popcorn failure when there is a temperature change. In accordance with embodiments the isolated underfill regions and/or isolated edge bond regions can be selectively applied at critical areas, such as high stress regions and locations where the solder bumps or other parts can have a relatively higher risk of failure, to reduce the risk level while also providing vent pathways for outgassing and thermal management.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “to”, “between”, “spanning” and “on” as used herein may refer to a relative position of one layer with respect to other layers. One layer “spanning” or “on” another layer or bonded “to” or in “contact” with another layer may be directly in contact with the other layer or may have one or more intervening layers. One layer “between” layers may be directly in contact with the layers or may have one or more intervening layers.

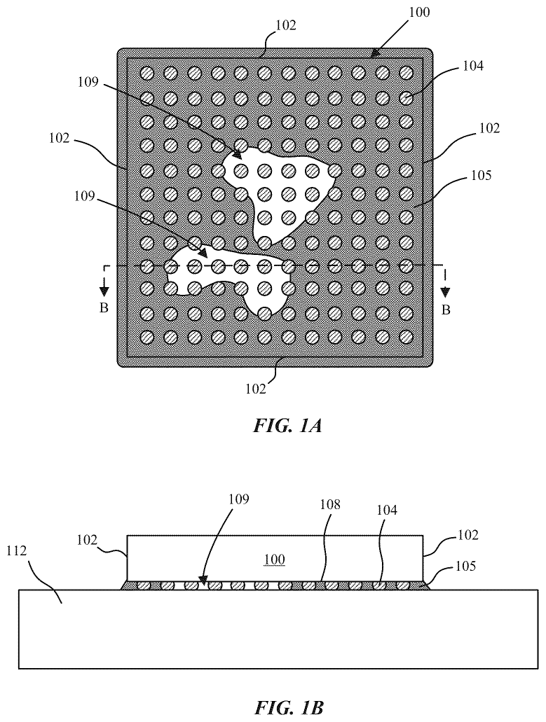

Referring now to FIGS. 1A-1B, FIG. 1A is a schematic top-down view illustration of an underfill material with voids applied underneath an electronic component; FIG. 1B is a schematic cross-sectional side view illustration taken along line B-B of FIG. 1A of an underfill material with voids applied underneath an electronic component. The particular configuration illustrated can be symptomatic of underfill difficulties with a large electronic device. As shown, the microelectronic structure includes a substrate 112, an electronic device 100 bonded to the substrate 112 with an array of solder bumps 104, and an underfill material 105 between the electronic device 100 and the substrate 112. As shown, one or more voids 109 can result in the underfill material 105 underneath the bottom surface 108 of the electronic device 100. The voids 109 may be completely surrounded by the underfill material 105, with no vent pathways to the edges 102 of the electronic device 100. In accordance with embodiments, various isolated underfill region and/or isolated edge bond region configurations are described in which vent pathways are formed. While it may be challenging to completely eliminate formation of voids 109, the size of any such voids in some embodiments may be limited to being no more than the minimum dimension of a length or width of the vent pathways and vent openings that are formed.

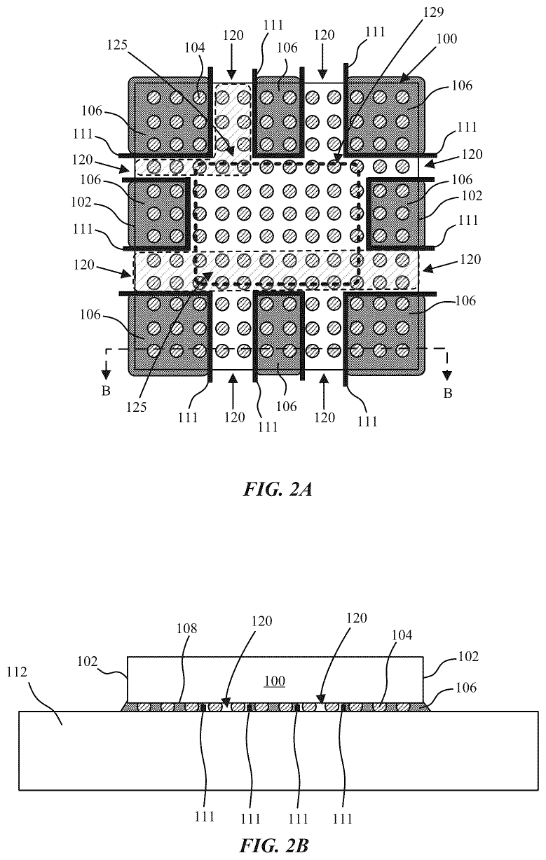

Referring now to FIGS. 2A-2B, FIG. 2A is a schematic top-down view illustration of a plurality of isolated underfill regions adjacent to one or more edges of an electronic device in accordance with an embodiment; FIG. 2B is a schematic cross-sectional side view illustration taken along line B-B of FIG. 2A of a plurality of isolated underfill regions adjacent to one or more edges of an electronic device in accordance with an embodiment. As shown, the microelectronic structure can include a substrate 112 and an electronic device 100 bonded to the substrate with an array of solder bumps 104. The substrate can be a variety of substrates including electrical routing, such as a printed circuit board (PCB), interposer, etc. The electronic device 100 can similarly be a die (logic, memory, power management integrated circuit, etc.), a package (which may include one or more dies or components), an active component (amplifier, integrated circuit, etc.), a passive component (resistor, capacitor, inductor, etc.), and a routing substrate (e.g. PCB, interposer, etc.).

In accordance with an embodiments, an underfill material is applied between the electronic device 100 and the substrate 112 where the underfill material includes a plurality of isolated underfill regions 106 adjacent to one or more edges 102 of the electronic device 100. As used herein, the term “isolated” means physically separate from one another. As shown, each isolated underfill region 106 can encapsulate a corresponding group of solder bumps 104 of the array of solder bumps. Additionally, a plurality of vent openings 120 is located along the one or more edges 102 and between the plurality of isolated underfill regions 106. In the specific embodiment illustrated, the vent openings 120 are defined by immediately adjacent isolated underfill regions 106 on either side of each vent opening 120.

In accordance with embodiments, the underfill material can be selectively dispensed to form the plurality of isolated underfill regions 106. Suitable underfill materials include curable polymers, such as epoxy that may include particle fillers. Selective application of the isolated underfill regions 106 can optionally be at corner regions, side regions, or any high stress region or critical location. The isolated underfill regions 106 can span underneath one or more, or all, corners of the electronic device. Such selective application can also facilitate reworkability of the microelectronic structure. While not required, in some embodiments ingress of the plurality of isolated underfill regions 106 underneath the electronic device 100 (i.e. ingress beyond the edges 102 toward a center area) can be confined by a pattern 111 on the substrate 112. For example, such a pattern may be a solder mask pattern, though the pattern 111 could be formed of other materials (such as passivation layers, or even a metal layer used to form metal contact pads) to confine the flow of the underfill material prior to, and after, curing.

The venti pathways in accordance with embodiments may facilitate thermal management with by providing an air gap, as well as fluid path for the flow of air and outgassing products. A variety of vent pathways can be designed depending upon application. In an embodiment, the plurality of vent openings 120 includes a first vent opening and a second vent opening, where the first vent opening is fluidly connected to the second vent opening with a first vent pathway 125. The first and second vent openings 120 may be located along the same or different edges 102, including orthogonal and opposite edges. Furthermore, the vent pathways 125 may encompass corresponding pluralities of solder bumps 104 that are not encapsulated by the underfill material.

In accordance with embodiments, the multiple vent openings 120 can be connected to multiple corresponding vent pathways 125. The vent pathways 125 can additionally be fluidly connected. For example, the vent pathways 125 can directly overlap, or intersect at a vent cavity 129, which can for example be centrally located underneath the electronic device 100. In accordance with embodiments, the vent pathways can connect vent openings on the same edge, orthogonal edges, or opposite edges of the electronic device.

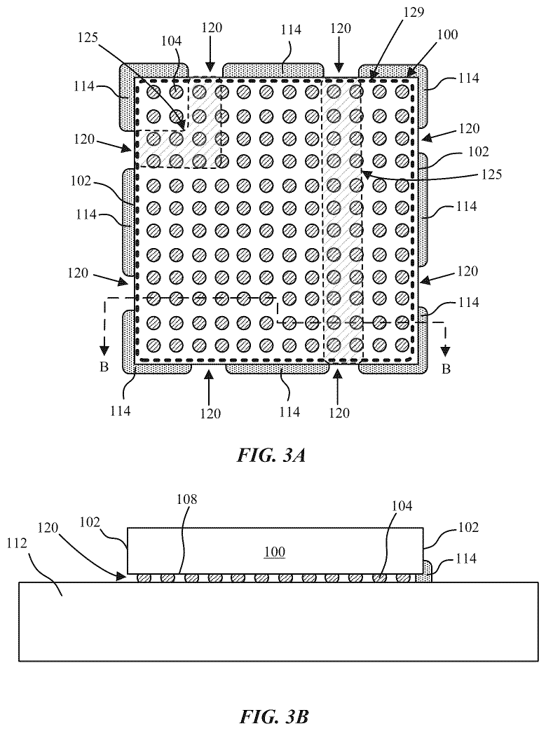

Referring now to FIGS. 3A-3B, FIG. 3A is a schematic top-down view illustration of a plurality of isolated edge bond regions adjacent to one or more edges of an electronic device in accordance with an embodiment; FIG. 3B is a schematic cross-sectional side view illustration taken along line B-B of FIG. 3A plurality of isolated edge bond regions adjacent to one or more edges of an electronic device in accordance with an embodiment. As shown, the microelectronic structure includes a substrate 112, an electronic device 100 bonded to the substrate with an array of solder bumps 104, and a plurality of isolated edge bond regions 114 adjacent to one or more edges 102 of the electronic device 100. In accordance with embodiments, a plurality of vent openings 120 can be located along the one or more edges 102 and between the plurality of isolated edge bond regions 114. In particular, the vent openings 120 can be defined by adjacent isolated edge bond regions 114. The edge bond material may be similar to the material used for the underfill material, though applied with a lower viscosity prior to curing. In an embodiment, the cured edge bond material is characterized by an elastic modulus greater than 1 GPa in the temperature range of −40° C. to 100° C.

Similar to the description with regard to FIGS. 2A-2B, the plurality of vent openings 120 along the one or more edges may be fluidly connected with vent pathways 125, which can encompass pluralities of solder bumps 104. Since the edge bond regions 114 do not substantially underfill the electronic device 100, the vent pathways may be fluidly connected with a vent cavity, which may correspond substantially to the footprint (area) of the electronic device 100. Likewise, the isolated edge bond regions 114 can span along one or more corners, or all corners, of the electronic device, as well as edges 102.

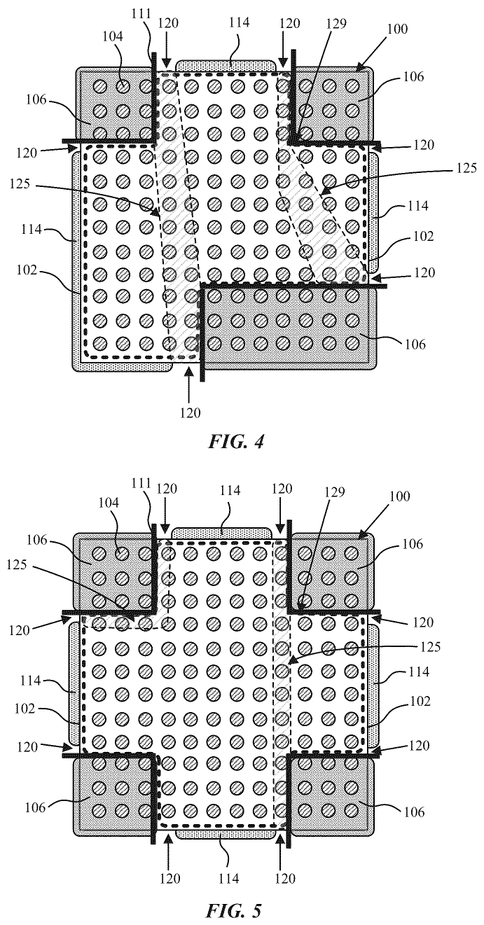

The isolated underfill regions and isolated edge bond regions described with regard to FIGS. 2A-2B and FIGS. 3A-3B can also be combined in hybrid structures in accordance with embodiment. FIGS. 4-5 are schematic top-down view illustrations of a plurality of isolated underfill regions 106 and isolated edge bond regions 114 adjacent to one or more edges 102 of an electronic device in accordance with embodiments. As shown in FIGS. 4-5, in addition to the vent openings being defined by two adjacent isolated underfill regions, and two adjacent isolated edge bond regions, the vent openings 120 can also be defined by an adjacent isolated underfill region 106 and an adjacent isolated edge bond region 114. Similar to previous description, various vent openings 120 along same edges 102, orthogonal edges 102, and opposite edges 102 can be fluidly connected with vent pathways 125. In a specific embodiment, the isolated underfill regions 106 may span underneath one or more corners of the electronic device 100, while isolated edge bond regions 114 can be applied along the edges 102 to provide additional structural support. Various alternative arrangements are also envisioned.

The embodiments of isolated underfill regions 106, isolated edge bond regions 114, and hybrid structures thereof can be implemented with a variety of bonding configurations, including controlled collapse chip connection (C4) bonding of dies, chip-scale package (CSP) bonding, (e.g. where the die size is typically no larger than 1.2 times the size of the package), ball grid array (BGA) package or interposer bonding, etc. Thus, the embodiments may be used for die bonding, package bonding, substrate/interposer bonding, etc.

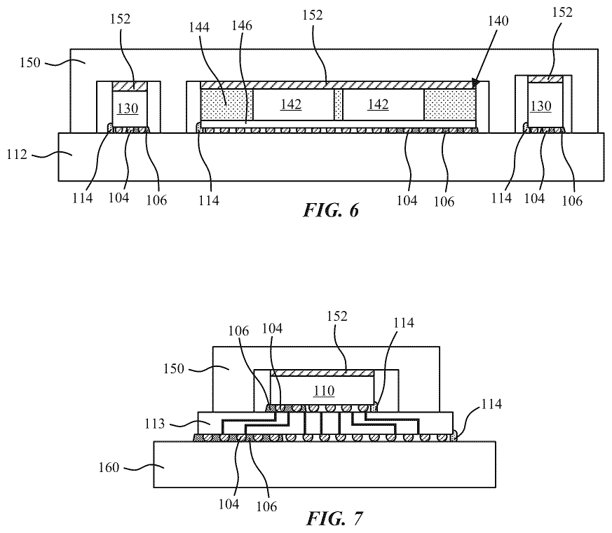

FIGS. 6-7 are schematic cross sectional side view illustrations of various microelectronic structures in accordance with embodiments. In the particular embodiment illustrated in FIG. 6 a lid 150 is bonded to substrate 112, such as a printed circuit board (PCB). The lid 150 may for example be formed of a metal, and may be adhesively bonded to the substrate 112 using suitable materials, such as polymer, solder, etc. Various electronic devices may also be bonded to the substrate 112, and underneath the lid such as CSPs 130, as well as a package 140 including multiple dies 142. For example, the dies 142 may be encapsulated with an insulating material 144, such as polymer molding compound, oxide fill, etc. A redistribution layer 146 can then be connected with the dies 142, and include metal redistribution routing. The CSPs 130 may be bonded to the substrate 112 with solder bumps 104, and secured using any combination of isolated underfill regions 106, isolated edge bond regions 114, and hybrid structures thereof described herein. Likewise, the package 140 can be bonded to the substrate 112 with solder bumps 104, and secured using any combination of isolated underfill regions 106, isolated edge bond regions 114, and hybrid structures thereof described herein. A thermal interface material (TIM) 152 can be applied on top of the CSPs 130 and package 140 for thermal connection with the lid 150.

In the particular embodiment illustrated in FIG. 7, a routing substrate 113 is bonded to a substrate 160, such as main logic board (MLB) with solder bumps 104, and secured using any combination of isolated underfill regions 106, isolated edge bond regions 114, and hybrid structures thereof described herein. The routing substrate 113 can for example be an interposer with electrical interconnections from the top to bottom sides. For example, such an interposer may be a silicon interposer, cored PCB, coreless PCB, etc. An electronic device, such as a die 110 or active/passive component, can in turn be bonded to the routing substrate 113 with solder bumps 104, and secured using any combination of isolated underfill regions 106, isolated edge bond regions 114, and hybrid structures thereof described herein. A lid 150 may be attached to the routing substrate 113 and the electronic device using suitable adhesive and TIM 152 as previously described.

In utilizing the various aspects of the embodiments, it would become apparent to one skilled in the art that combinations or variations of the above embodiments are possible for selectively dispensing underfill and edge bond patterns. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A microelectronic structure comprising:
a substrate;
an electronic device bonded to the substrate with an array of solder bumps;
an underfill material between the electronic device and the substrate, wherein the underfill material includes a plurality of isolated underfill regions adjacent to one or more edges of the electronic device, wherein each isolated underfill region encapsulates a corresponding group of solder bumps of the array of solder bumps; and
a plurality of vent openings along the one or more edges and between the plurality of isolated underfill regions.

2. The microelectronic structure of claim 1, wherein the plurality of vent openings comprises a first vent opening and a second vent opening, wherein the first vent opening is fluidly connected to the second vent opening with a first vent pathway.

3. The microelectronic structure of claim 2, wherein the first vent opening is along a first edge of the one or more edges and the second vent opening is along a second edge of the one or more edges.

4. The microelectronic structure of claim 2, wherein the first vent pathway encompasses a first plurality of solder bumps of the array of solder bumps.

5. The microelectronic structure of claim 2, wherein the plurality of vent openings comprises a third vent opening and a fourth vent opening, wherein the third vent opening is fluidly connected to the fourth vent opening with a second vent pathway.

6. The microelectronic structure of claim 5, further comprising a vent cavity, wherein the first vent pathway and the second vent pathway are fluidly connected with the vent cavity.

7. The microelectronic structure of claim 1, wherein the plurality of isolated underfill regions includes:
a first isolated underfill region that spans underneath a first corner of the electronic device;
a second isolated underfill region that spans underneath a second corner of the electronic device; and
a third isolated underfill region that spans underneath a third corner of the electronic device.

8. The microelectronic structure of claim 1, wherein the electronic device is selected from the group consisting of a die, a package, an active component, a passive component, and a routing substrate.

9. The microelectronic structure of claim 1, further comprising a plurality of isolated edge bond regions adjacent to the one or more edges of the electronic device.

10. The microelectronic structure of claim 9, wherein a first vent opening of the plurality of vent openings is between a first isolated edge bond region of the plurality of isolated edge bond regions and a first isolated underfill region of the plurality of isolated underfill regions.

11. The microelectronic structure of claim 10, wherein a second vent opening of the plurality of vent openings is between the first isolated edge bond region of the plurality of isolated edge bond regions and a second isolated underfill region of the plurality of isolated underfill regions.

12. The microelectronic structure of claim 11, wherein the first vent opening and the second vent opening are along a same edge of the electronic device, the first isolated underfill region spans underneath a first corner of the electronic device, and the second isolated underfill region spans underneath a second corner of the electronic device.

13. The microelectronic structure of claim 1, wherein ingress of the plurality of isolated underfill regions underneath the electronic device is confined by a pattern on the substrate.

14. The microelectronic structure of claim 13, wherein ingress of the plurality of isolated underfill regions underneath the electronic device is confined by a solder mask pattern.

15. A microelectronic structure comprising:
a substrate;
an electronic device bonded to the substrate with an array of solder bumps;
a plurality of isolated edge bond regions of an edge bond material adjacent to one or more edges of the electronic device; and
a plurality of vent openings along the one or more edges and between the plurality of isolated edge bond regions.

16. The microelectronic structure of claim 15, wherein the plurality of vent openings comprises a first vent opening and a second vent opening, wherein the first vent opening is fluidly connected to the second vent opening with a first vent pathway.

17. The microelectronic structure of claim 16, wherein the first vent opening is along a first edge of the one or more edges and the second vent opening is along a second edge of the one or more edges.

18. The microelectronic structure of claim 16, wherein the first vent pathway encompasses a first plurality of solder bumps of the array of solder bumps.

19. The microelectronic structure of claim 16, wherein the plurality of vent openings comprises a third vent opening and a fourth vent opening, wherein the third vent opening is fluidly connected to the fourth vent opening with a second vent pathway.

20. The microelectronic structure of claim 19, further comprising a vent cavity, wherein the first vent pathway and the second vent pathway are fluidly connected with the vent cavity.

21. The microelectronic structure of claim 1, wherein the plurality of isolated underfill regions includes:
a first isolated edge bond region that spans along a first corner of the electronic device;
a second isolated edge bond region that spans along a second corner of the electronic device; and
a third isolated edge bond region that spans along a third corner of the electronic device.

22. The microelectronic structure of claim 15, wherein the electronic device is selected from the group consisting of a die, a package, an active component, a passive component, and a routing substrate.
